(19) United States
(12) Patent Application Publication
(10) Pub. No.: US 2013/0244052 A1
(43) Pub. Date: Sep. 19, 2013

(54) Forming a Metallic Cladding on an Architectural Component

(71) Applicant: Michael A Mullock, Bryn Mawr, PA (US)

(72) Inventor: Michael A Mullock, Bryn Mawr, PA (US)

(21) Appl. No.: 13/423,236

(22) Filed: Mar. 18, 2012

(51) Int. Cl. B21D 39/00; C23C 14/02; C23C 4/12; C23C 14/34

(52) U.S. Cl. 428/622; 427/8

(57) ABSTRACT

A metallic cladding is provided onto a substrate of an architectural component such as a door or window by beginning sputter welding of a primary metallic layer onto a surface of a substrate of an architectural component; while maintaining a temperature of the surface of the substrate at or below a temperature threshold to avoid damage or outgassing to the substrate, continuing the sputter welding until a pre-determined thickness of the primary metallic layer is achieved; depositing a secondary metallic layer onto the primary metallic layer, wherein the secondary metallic layer is formed up to a secondary thickness less than the pre-determined thickness of the primary metallic layer; and applying one or more protective coats of an essentially transparent material loaded with a metallic substance to the secondary metallic layer.

### FIELD OF THE INVENTION

The invention generally relates to tools and processes for adding a metallic protective cladding layer to materials commonly used in windows and doors, and especially to historic windows and doors.

### BACKGROUND OF INVENTION

Architectural components and elements such as doors, windows, sconces, moldings and trim pieces are often fabricated from materials such as wood, plaster, cement, polystyrene, tin, aluminum, copper, bronze, medium density fiberboard (MDF), polyvinyl chloride (PVD) and fiberglass. Many of these materials are not impervious to elements such as wind, rain, ice, and humidity without additional protective layers, such as paint or metal cladding.

These unprotected materials tend to be less expensive, and often appear on less expensive structures and buildings. In particular, historic buildings which are intended to endure long periods of time with little or no maintenance are provided with such high end architectural components. Thus, one manner in which more expensive, stately or artistic buildings are distinguished over more common structures is in the use, or at least the apparent use, of bronze, copper and other metallic components such as doors, windows, and other architectural components.

Some methods are known in the art for providing such “high end” appearance to components made of less expensive materials, and some methods are known for retrofitting or “refurbishing” such lower end components to have such an appearance.

### SUMMARY OF THE DISCLOSURE

A metallic cladding is provided onto a substrate of an architectural component such as a door or window by beginning sputter welding of a primary metallic layer onto a surface of a substrate of an architectural component; while maintaining a temperature of the surface of the substrate at or below a temperature threshold to avoid damage or outgassing to the substrate, continuing the sputter welding until a pre-determined thickness of the primary metallic layer is achieved; depositing a secondary metallic layer onto the primary metallic layer, wherein the secondary metallic layer is formed up to a secondary thickness less than the pre-determined thickness of the primary metallic layer; and applying one or more protective coats of an essentially transparent material loaded with a metallic substance to the secondary metallic layer.

### BRIEF DESCRIPTION OF THE DRAWINGS

The description set forth herein is illustrated by the several drawings.

FIG. 1 illustrates a process according to the present invention for providing a metallic cladding to a substrate such as an architectural component (door, window, etc.)

FIG. 2 provides a cross-sectional view of a portion of an example architectural element, a window in this instance, and a present surface profile onto which a metallic cladding is to be deposited.

FIG. 3 shows an example cladding provided according to the methods of the present invention to the example architectural component of FIG. 2.

### DETAILED DESCRIPTION OF EMBODIMENT(S) OF THE INVENTION

Discovery of a Problem.

The inventor of the present invention has recognized problems not yet recognized by those skilled in the relevant arts. There exists in the construction marketplace a need for high quality exterior finishes on windows and doors using weathered metal cladding for security, aesthetics and weathering resistance.

Restored legacy building exteriors and high-end private and institutional structures use metal clad doors and windows to evoke the design elements of strength, longevity, and aesthetics of burnished and oxidized metals, much as public sculptures often employ oxides of brass, bronze, copper and steel.

There are two current commercial methods for achieving the clad metal appearance desired by this large and valuable marketplace: (1) roll-formed metal sheet cladding, and (2) painting the exterior of the doors and windows with highly-loaded metal and metal oxide paints.

Roll-formed metal cladding uses long strips of flat metal or metal oxide sheet material. These strips of metal sheet are sequentially bent into a desired shape as they are dragged through a series of rollers and dies. These sheets are typically 1/16-inch thick or thicker to ensure they properly resist handling and assembly damage. After the desired shape is achieved, these shaped metal pieces are affixed to a similarly shaped substrate by press fitting the substrate, typically wood, together with the cladding sheet. This fitting can be augmented with either fasteners or adhesives. Intersecting door and window joints must be fitted together and the joints soldered or otherwise joined and made impervious to moisture penetration.

The process of bending, cutting, fitting and joining these intersecting sections into a final window or door assembly embodies a number of difficulties which make it expensive and also limit its utility and aesthetics:
(a) it is labor intensive and complex, with many steps, making automation difficult to achieve even for large volumes of same items;
(b) it is material intensive as the fragility of the extruded or roll formed profiles make it is necessary for the manufacturer to use higher gauge and thicker materials, unnecessarily wasting metals that are increasingly more expensive;
(c) tooling and job setup is expensive and unique to the shape and aesthetics desired, so short runs are very costly.

This process is also difficult to adapt to complex shapes which may be found on windows and doors. Many modern architectural designs are replications of historic models. Roll formed metal or extruded metal profiles are difficult to bend without distortion. They require complicated tooling not readily available to many small and medium fabrication shops. Due to these limitations, the metal cladding is restricted to standard profiles that may be unacceptable to the designer or not in compliance with matching historic details.

There is a risk that extruded or roll-formed profiles can be distorted or dented in the roll forming or storage or in assembly. Finish, alignment, and assembly to achieve a perfect joining of the finish joints is relatively difficult. Once assembled, they are very difficult if not impossible to repair if damaged.

Further, the assembled cladding pieces' coefficients of expansion often varies significantly from the coefficient's of expansion for the substrate(s) to which they are applied, which can create voids and cracks at different temperatures and humidity levels, in which moisture can lodge and cause decay and failure.

Still further, windows and doors made from this process can be extremely heavy and require special installation handling and supporting structures, which makes installation even more expensive.

In the second method of adding a metallic cladding to a door or window, highly loaded metal or metal oxide pigmented paints are applied to the substrate to achieve an appearance of metal cladding on the window or door exteriors. In this process, the window or door frame is assembled, then the substrate surfaces are sanded in order to remove any smooth surfaces to enhance the adherence of the paint. Then, a liquid solvent base paint which has been highly loaded with metal or metal oxide pigments is applied manually to the outer surfaces.

The orientation of the frame is critical for the proper flow of the paint across the window or door frame during the deposition, settling and drying process and may require multiple primer coat applications in order to properly coat the frame. Composite and polymer frames do not readily absorb paint solvents and so are not used, leaving wood as the only practical substrate for this process. After the primer coat or coats thoroughly dry, which can take several days even with drying systems because of the viscous nature of highly loaded primers, the surface is then sanded to smooth out any imperfections in paint flow and to prepare the surface to more readily receive the exterior coat.

The exterior coat, also a solvent-based paint highly loaded with metal or metal oxide pigments, is then applied by brush or spray gun onto the primer surface of the frame in conventional fashion. After drying, which due to the thick coats of primer and paint even with drying systems may require several days to achieve, the exterior coating is sanded to smooth and polish its appearance. A second exterior coat may be required to achieve a commercially acceptable clad metal appearance since the requirement for the solvent carrier base limits the amount of metal or metal oxide pigment that can be deposited in any one coat.

When complete, the window or door frame has a continuous coating of metal or metal oxide particles without the joints or difficulty in following complex shapes that limit roll-formed metal cladding, however the painting approach has several disadvantages:
(a) it is slow and requires a very large amount of skilled application and finishing effort, repeated many times, and as such is quite expensive;
(b) it is limited primarily to wood substrates since paint does not adhere readily or well to composites and polymers;
(c) but because wood frames are heavy, they can experience problems when they swell or shrink in varying humidity conditions, and are relatively expensive to make and maintain, they are not the preferred material for most windows and many doors; and
(d) while esthetically pleasing and functional, the painting method does not provide a solid metal shield like roll-formed cladding because the maximum practical achievable metallic pigment loads are in the 65% range with the 35% or greater remainder being chemical constituents of the carrier base, wherein the chemical components degrade from environmental exposure and eventually moisture can penetrate through those chemical components and affect the wood substrate.

Because of the threat of damage from moisture, most window and many door frames are made from composite or polymer materials which are highly resistant to moisture penetration, are much lighter, and are easy to convert into a variety of shapes and sizes. However, such windows and doors do not satisfy the aesthetic requirements sought by the premium market and as such are typically used in medium and lower cost markets, and they are not suitable for either of the traditional methods of applying metal cladding, e.g. roll-formed metal clads or highly-loaded metallic paints.

New Sputter-based Metallic Clad Forming Process.

The present inventors have realized these problems with the existing methods and processes, and have developed through deterministic and experimental efforts a system of tools, materials, process conditions and controls that provides a practical option for achieving the aesthetic benefits and weathering resistance of metal cladding, which can readily cover complex substrate shapes, and which can be provided to a door or window easily and at much lower consumption of labor, material, time and special tools. An additional advantage to the new inventive process is that it can be utilized to apply a metal cladding not only to wood substrates, but also to composite and polymer substrates.

The process, which we will refer to as thermally-managed sputtering metallic cladding deposition, eliminates the first coat or primer process of the painting method, and completely eliminates the forming and attachment of sheet metal, while achieving impermeability greater than the painting method and rivaling that of the rolled metal method without the potential for voids and gaps between the cladding and the substrate.

Processes according to the invention replace the primer coating process of paint described above with the direct application of metal and/or metal oxides onto the surface of the substrate using specialized tools under specific process conditions of time, temperature and technique. In this process, the initial coat of metal or metal oxide is applied to the substrate by precisely heating the metal/metal oxide with acetylene and then spraying it at certain temperatures.

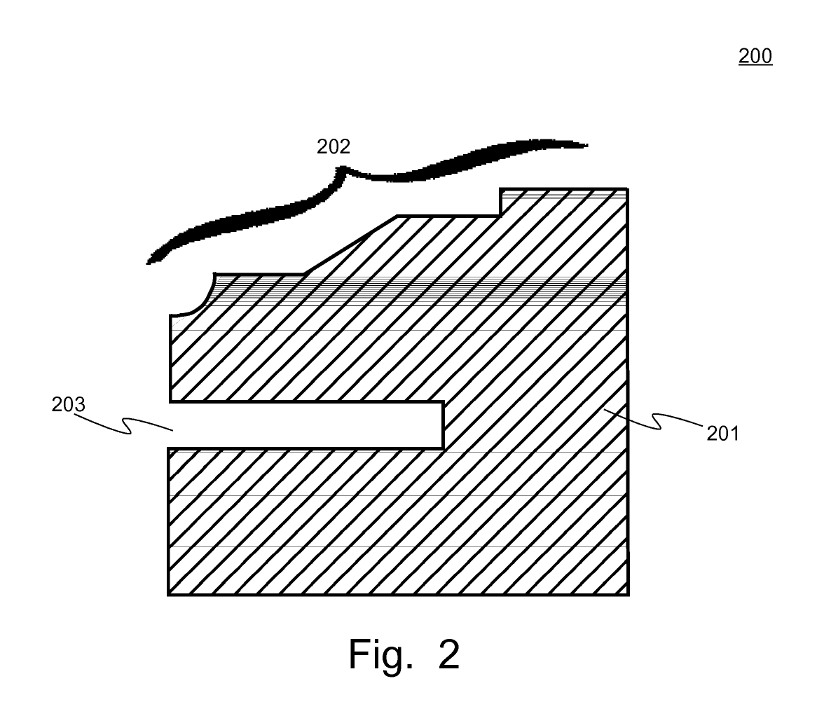

Referring to FIG. 2, an example of a cross-sectional view (200) of a window frame (201) is shown, which presents a slot or groove (203) for receiving a pane of glass, and which presents an exterior surface (202) having a decorative profile, such as a combination of flat, curved and angled surfaces. This particular profile is complicated enough to envision the difficulties of forming a metal sheet for fitting over the surface, and the difficulties of managing paint thickness and paint running using the afore-mentioned painting process.

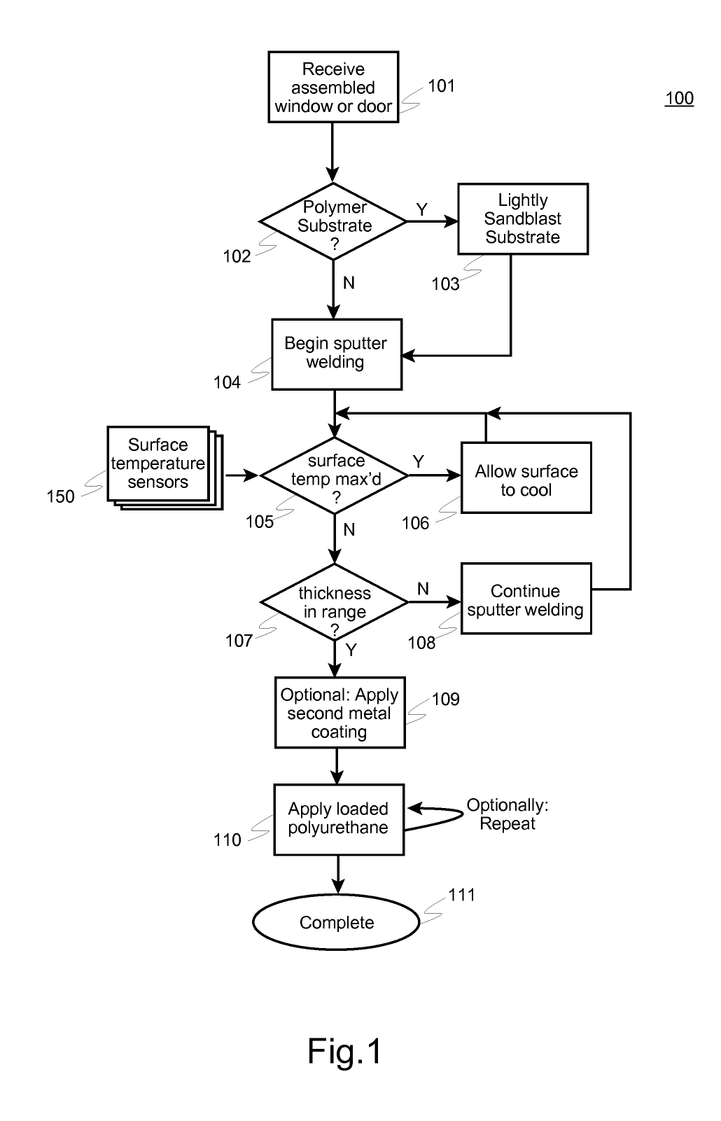

Referring now to FIG. 1, the first step of an exemplary process (100) according to the invention is to receive an assembled window frame or door (101). Unlike the previously-described painting process, the assembled frame does not require any extensive surface preparation, though some polymer frames are more easily coated if the surface is lightly sandblasted (102, 103) to score it.

Using an ethylene-fueled metal flame sprayer, such as a handheld unit, fed with metallic wire, such as zinc wire, sputter welding is started (104) on the surface of the substrate. Other metals may be substituted for or combined with zinc, however the inventors experiments have shown that zinc provides a reliable and easy-to-apply metal coating across a wide array of substrates.

The applied surface is monitored (150, 105, 106) so that the substrate surface temperature is maintained at less than 90C, and preferably less than 60C, to prevent burning or offgassing from the substrate of moisture or volatile organic compounds within it. The burning or offgassing may interfere with adhesion of the sputtered metal to the substrate.

Sputter welding of the first layer of cladding is continued (107, 108) until a 0.004 to 0.012 inch thick layer of zinc metal is achieved on the surface of the frame, covering it completely or at least for the portions which will be exposed to harmful conditions (weather, sunlight, humidity, etc.).

Again, differentiating from the final steps of the painting method, sanding the deposited metal cladding is neither necessary nor desirable after application of the desired thickness of zinc (or other metal) coating is complete. At this stage the coating has a much higher percent of metal on the substrate than can be achieved with paint or primers, approximately 95%, but it still has a slight permeability of approximately 5%.

Optionally, an additional coating of less than 0.004 inch can be sputtered (109) onto the first layer, such as aluminum bronze wire flame sprayed and sputtered to the surface to vary the hue and texture of the finished coating, depending on the finish desired. This optional layer may tend to further reduce the permeability of the cladding being formed on the substrate.

In the next step, a highly loaded combination of pre-oxidized copper, bronze or stainless steel powder is mixed with a catalyzed polyurethane, and applied (110) to the cladding using a high volume, low pressure application gun. This process is optionally repeated three times according to at least one embodiment of the inventive process.

The final surface is allowed to dry and then, optionally, lightly sanded until the exterior finish is smooth. This completes (111) the manufacturing process except for the standard glazing/glass addition steps that are normally required for any window or door with glass panels.

Advantages of processes according to the invention include, but are not limited to:
(a) Costs—cladding metal and highly loaded paints are expensive and highly labor intensive to fabricate and apply. The sputter metal coating allows for very precise placement of the metal with little overspray or waste, so the total amount and cost of material used is substantially lower than the alternate methods.
(b) Speed—sputter metal coating is simple and fast, permitting an initial coating to be completed in minutes and completion of all finishing operations in 48 hours from start to finish, with approximately 20% of the effort hours necessary for other methods.
(c) Substrate flexibility—all common window and door substrates can be coated with this method, so that low cost of production polymer and composite substrates can be converted into aesthetically pleasing, premium market products.
(d) Simplicity—reduces need for skilled labor since the coating method is simple and easily automated.
(e) Light weight—cladding and frame combined weight is much lower than wood and traditional coating/cladding methods so the product is much easier to handle, ship and install, and does not require special supports or heavier beams etc. Distribution cost of these products is much lower.
(f) Durability—the high-percent metal, low permeability cladding resulting from the methods according to the present invention do not depend on polymer adhesion to the substrate for effectiveness and has a much higher density of metal than paint systems, and so performs similar to solid sheet with the additional benefit of no voids between the coating and substrate.
(g) Insensitivity to moisture on composite substrates—the combination of high quality metal barrier coating and substrate moisture resistance typical of polymer systems offers a uniquely moisture resistant and aesthetically pleasing metal clad window or door solution.

At least the following aspects of processes and methods according to the present invention are believed to be unique, inventive and distinguishing over the known processes and methods of forming or applying a metal cladding over architectural building element substrates:
(a) applying a metal cladding according to the present invention onto polymers such as polyvinyl chloride (PVC), fiberglass and their combinations such as fiberglass filled PVC, can be accomplished by including lightly scouring with sandblasting or similar techniques, which extends the invention's usefulness beyond applications just to wood architectural elements.
(b) applying a metal cladding according to the present invention onto assembled architectural components with a substantial amount of three-dimensional features (shapes, moldings, curves, etc.) facilitates adherence (e.g. “grab”) by the primary zinc layer as it cools and shrinks.
(c) Using zinc as first or primary cladding layer applied at a lowest temperature that will adhere to the substrate can be done, by our measurement system between, 30C and 75C.
(d) Applying a second and subsequent metal clad coats for the desired aesthetic affect that are no thicker than one-third (⅓) of the thickness of the first zinc layer can avoid remelting or delamination of the primary zinc layer.
(e) Methods according to the present invention may be performed without any sanding or surface preparation of each metal spray layer, unlike other sputtering methods in the known art.
(f) A final coating may optionally be a paint carry heavily loaded with the appropriate metal powder to fill in the small amount of porosity from air spraying and to ensure a highly weather resistant coating on a highly moisture resistant substrate for maximum window longevity.
(g) A final coat may be optionally sanded as needed for smoother finish.

Using some or all of these method elements according to the invention, the new process avoids delamination, eliminates interim surface preparation steps, provides a superior substrate for weathering, specifies the correct metal primary coating and the details of applying secondary metal spray coatings, and properly seals and smooths the final product by application of the highly loaded metal powder in liquid carrier for best long-term performance and lowest labor input.

Inventive Metallic Cladding.

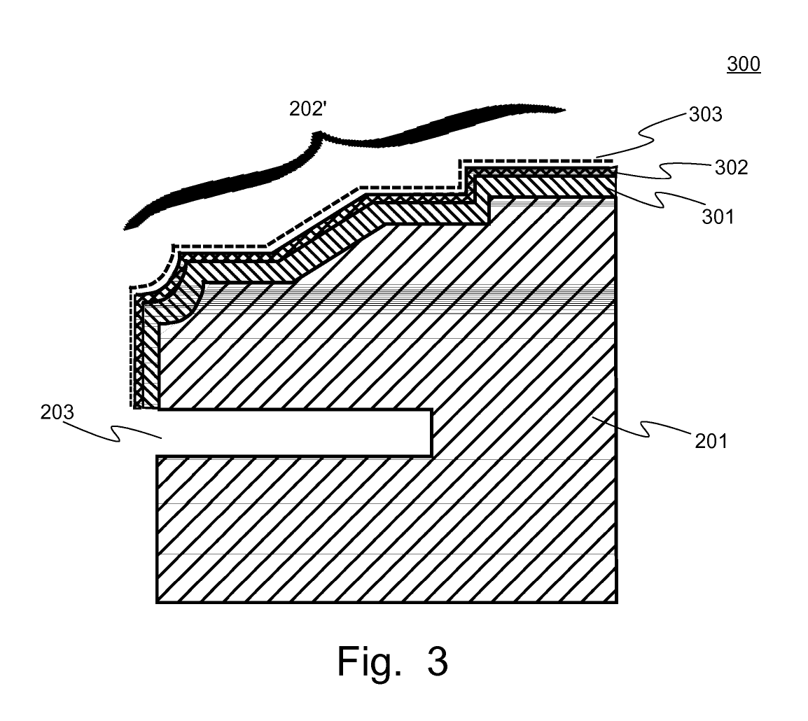

The inventors have determined that the cladding layers according to the present invention as illustrated in FIG. 3 in cross-sectional view (300) are superior in performance, weight, adherence to detailed and complicated surface profiles over temperature and humidity ranges, acceptable impermeability of outside elements to yield effective protection of the architectural element, and in aesthetic appearance over the methods of the known art. A first metallic layer (301) is provided directly on the substrate of the surface of the substrate. A secondary (302) metallic layer is formed on the primary metallic layer, opposite of the substrate surface. And, one or more protective coatings are provided onto the secondary metallic layer, opposite of the first metallic layer, thereby creating at least three layers of protection to yield a complete cladding of the surface (202) of the architectural element, reliably adhering to and faithfully reproducing the profile of the surface.

### CONCLUSION

The terminology used in this disclosure is provided for the purpose of illustrating and explaining particular example embodiments, and the terminology and example embodiments are not intended to be limiting of the invention. The singular forms “a”, “an” and “the” are intended to include the plural forms as well, unless indicated otherwise. Terms “comprises” and/or “comprising” in this specification specify the presence of stated features, steps, operations, elements, or components, without precluding the presence or addition of one or more other features, steps, operations, elements, components, and/or groups thereof, unless stated otherwise. Modifications and variations of the processes and systems disclosed will be apparent to those of ordinary skill in the art without departing from the scope and spirit of the invention.

What is claimed is:

1. A process for providing a metallic cladding onto a substrate of an architectural component comprising:
beginning sputter welding of a primary metallic layer onto a surface of a substrate of an architectural component;
while monitoring a temperature of the surface of the substrate:
continuing the sputter welding responsive to the substrate surface temperature being detected below a pre-determined threshold and until a pre-determined thickness of the primary metallic layer is achieved;
responsive to detecting the surface temperature exceeding a pre-determined threshold, suspending sputter welding for a period of time for cooling;
responsive to the elapse of the period of time for, continuing the sputter welding until the pre-determined thickness of the primary metallic layer is achieved;
thereby avoiding damage or offgassing from the substrate;
depositing a secondary metallic layer onto the primary metallic layer, wherein the secondary metallic layer is formed up to a secondary thickness less than the pre-determined thickness of the primary metallic layer; and
applying one or more protective coats of an essentially transparent material loaded with a metallic substance to the secondary metallic layer.

2. The process as set forth in claim 1 further comprising, prior to the beginning of sputter welding of the primary metallic layer, for an architectural component substrate which presents a smooth surface onto which a metallic cladding is to be formed, modifying the smooth surface to present a textured surface.

3. The process as set forth in claim 1 wherein the modifying of the smooth surface comprises sandblasting.

4. The process as set forth in claim 1 wherein the architectural component substrate comprises a non-organic material selected from the group consisting of polyvinyl chloride, fiberglass, and fiberglass-filled polyvinyl chloride.

5. The process as set forth in claim 1 wherein the architectural component substrate comprises an organic material.

6. The process as set forth in claim 1 wherein the architectural component comprises a window component.

7. The process as set forth in claim 1 wherein the architectural component comprises a door component.

8. The process as set forth in claim 1 wherein the pre-determined thickness of the primary metallic layer is between 0.004 to 0.012 inch.

9. The process as set forth in claim 1 wherein the substrate surface pre-determined temperature threshold is 90 centrigrade.

10. The process as set forth in claim 1 wherein the substrate surface pre-determined temperature threshold is 60 centrigrade.

11. The process as set forth in claim 1 wherein the substrate surface pre-determined temperature threshold is 30 centrigrade.

12. The process as set forth in claim 1 wherein the secondary metallic layer thickness is approximately one-third of the pre-determined thickness of the primary metallic layer.

13. The process as set forth in claim 1 wherein the primary metallic layer comprises a zinc layer.

14. The process as set forth in claim 1 wherein the depositing of a secondary metallic layer comprises flame spraying using an aluminum bronze wire.

15. The process as set forth in claim 1 wherein the primary metallic layer provides at least a 95% impermeability cladding to the substrate.

16. The process as set forth in claim 1 wherein sanding or steps of enhancing surface texture of the primary metallic coating prior to depositing the secondary metallic coating are avoided.

17. The process as set forth in claim 1 wherein the applying of one or more protective coats comprises applying catalyzed polyurethane loaded with a combination selected from the group consisting of pre-oxidized copper powder, bronze powder, and stainless steel powder.

18. The process as set forth in claim 17 wherein the applying of the protective coat is achieved at least in part using a high volume, low pressure application gun.

19. A metallic cladding for a substrate of an architectural component comprising:
a primary metallic layer sputter welded onto a surface of a substrate of an architectural component, wherein a temperature of the surface of the substrate is maintained at or below a pre-determined threshold during the sputter welding thereby avoiding damage or offgassing from the substrate, and wherein the primary metallic layer is sputter welded up to a pre-determined thickness;
a secondary metallic layer deposited onto the primary metallic layer, the secondary metallic layer having a thickness less than the pre-determined thickness of the primary metallic layer; and
one or more protective coats applied to the secondary metallic layer, the protective coat being of an essentially transparent.

20. The metallic cladding as set forth in claim 19 wherein the architectural component substrate comprises a non-organic material selected from the group consisting of polyvinyl chloride, fiberglass, and fiberglass-filled polyvinyl chloride.

21. The metallic cladding as set forth in claim 19 wherein the architectural component substrate comprises an organic material.

22. The metallic cladding as set forth in claim 19 wherein the architectural component comprises a window component.

23. The metallic cladding as set forth in claim 19 wherein the architectural component comprises a door component.

24. The metallic cladding as set forth in claim 19 wherein the pre-determined thickness of the primary metallic layer is between 0.004 to 0.012 inch.

25. The metallic cladding as set forth in claim 19 wherein the substrate surface temperature pre-determined threshold is 90 centrigrade.

26. The metallic cladding as set forth in claim 19 wherein the substrate surface pre-determined temperature threshold is 60 centrigrade.

27. The metallic cladding as set forth in claim 19 wherein the substrate surface pre-determined temperature threshold is 30 centrigrade.

28. The metallic cladding as set forth in claim 19 wherein the secondary metallic layer thickness is approximately one-third of the pre-determined thickness of the primary metallic layer.

29. The metallic cladding as set forth in claim 19 wherein the primary metallic layer comprises a zinc layer.

30. The metallic cladding as set forth in claim 19 wherein the secondary metallic layer comprises an aluminum bronze layer.

31. The metallic cladding as set forth in claim 19 wherein the primary metallic layer provides at least a 95% impermeability cladding to the substrate.

32. The metallic cladding as set forth in claim 19 wherein one or more of the protective coats comprises a catalyzed polyurethane loaded with a combination selected from the group consisting of pre-oxidized copper powder, bronze powder, and stainless steel powder.
